(19) United States
(12) Patent Application Publication
(10) Pub. No.: US 2019/0123119 A1
(43) Pub. Date: Apr. 25, 2019

(54) ORGANIC EL DISPLAY APPARATUS AND ACTIVE MATRIX SUBSTRATE

(71) Applicant: Sharp Kabushiki Kaisha, Sakai City (JP)

(72) Inventors: Tadayoshi MIYAMOTO, Sakai City (JP); Mari HOSOKAWA, Sakai City (JP); Yoshinobu NAKAMURA, Sakai City (JP); Hirohiko NISHIKI, Sakai City (JP)

(21) Appl. No.: 16/163,604

(22) Filed: Oct. 18, 2018

(30) Foreign Application Priority Data
Oct. 20, 2017 (JP) 2017-203350

(51) Int. Cl. H01L 27/32; H01L 51/52; H01L 51/50; H01L 29/786; H01L 29/49

(52) U.S. Cl. CPC H01L 27/3262; H01L 51/5253; H01L 51/5092; H01L 29/4908; H01L 27/3272; H01L 29/78609; H01L 29/7869; H01L 27/3248

(57) ABSTRACT

An organic EL display apparatus includes a substrate, and a pixel circuit provided for each pixel. The pixel circuit includes a first oxide semiconductor TFT having a first oxide semiconductor layer, and a second oxide semiconductor TFT having a second oxide semiconductor layer. The first oxide semiconductor TFT has a top-gate structure. The second oxide semiconductor TFT has a bottom-gate structure. The second oxide semiconductor TFT has a shield electrode that is disposed on an insulating layer disposed on the second oxide semiconductor layer, facing the second oxide semiconductor layer.

### BACKGROUND

### 1. Technical Field

The present invention relates to organic EL display apparatuses and active matrix substrates, and more particularly, to organic EL display apparatuses and active matrix substrates including oxide semiconductor TFTs.

### 2. Description of the Related Art

Thanks to the advances of the organic light emitting diode (OLED) technology, products having an organic electroluminescent (EL) display apparatus as a display section, ranging from large-sized televisions to high-definition smartphones, have in recent years been becoming widespread. As thin-film transistors (TFTs) for the backplanes of OLEDs, low-temperature polysilicon (LTPS)-TFTs have currently been widely used. It has been proposed that LTPS-TFTs may be replaced by oxide semiconductor TFTs, which are suitable for large areas and higher definition (e.g., Japanese Laid-Open Patent Publication No. 2015-195363). There has also been an increasing demand for production of TFTs using lower-cost processes.

A typical organic EL display apparatus has a pixel circuit including two TFTs and one capacitive element (storage capacitor). One of the two TFTs is called a selection TFT; and the other, a drive TFT. An example pixel circuit for an organic EL display apparatus is shown in FIG. 14. FIG. 14 is a cross-sectional view showing a pixel circuit 900Pc for a bottom-emission organic EL display apparatus. The pixel circuit 900Pc of FIG. 14 includes a selection TFT 910, a drive TFT 920, and a storage capacitor 930.

The selection TFT 910 has a gate electrode 911, a gate insulating layer 912, an oxide semiconductor layer 913, a source electrode 914, and a drain electrode 915. The drive TFT 920 similarly has a gate electrode 921, a gate insulating layer 922, an oxide semiconductor layer 923, a source electrode 924, and a drain electrode 925.

The selection TFT 910 and the drive TFT 920 are supported by a substrate 901. An underlying insulating layer (base coat layer) 902 is disposed on the substrate 901. The oxide semiconductor layers 913 and 923 are disposed on the underlying insulating layer 902.

The gate insulating layers 912 and 922 are disposed on the oxide semiconductor layers 913 and 923, respectively. The gate electrodes 911 and 921 are disposed on the gate insulating layers 912 and 922, respectively. An interlayer insulating layer 903 is provided to cover the oxide semiconductor layers 913 and 923 and the gate electrodes 911 and 921. The source electrodes 914 and 924 and the drain electrodes 915 and 925 are disposed on the interlayer insulating layer 903. The source electrode 914 and the drain electrode 915 are connected to the oxide semiconductor layer 913 through contact holes formed in the interlayer insulating layer 903. The source electrode 924 and the drain electrode 925 are connected to the oxide semiconductor layer 923 through contact holes formed in the interlayer insulating layer 903. A storage capacitor electrode 931 is also disposed on the interlayer insulating layer 903. The storage capacitor electrode 931 is electrically connected to the gate electrode 921 of the drive TFT 920.

In the example of FIG. 14, the selection TFT 910 and the drive TFT 920 both have a top-gate structure. A protection layer 905 is provided to cover the selection TFT 910 and the drive TFT 920. A color filter layer 906 is disposed on the protection layer 905. A planarization layer 907 is provided to cover the color filter layer 906.

An anode 941 is disposed on the planarization layer 907. The anode 941 is electrically connected to the drain electrode 925 of the drive TFT 920.

A bank 908 is disposed between adjacent pixels. The bank 908 covers a portion of the pixel electrode 941. An organic EL layer 942 is disposed on the pixel electrode 941. A cathode 943 is disposed on the organic EL layer 942. The cathode 943 continuously spreads throughout a display region.

The storage capacitor 930 includes a capacitor that is formed by the storage capacitor electrode 931, the anode 941, and the protection layer 905 interposed therebetween, and a capacitor that is formed by the storage capacitor electrode 931, the oxide semiconductor layer 923, and the interlayer insulating layer 903 interposed therebetween.

### SUMMARY

The selection TFT has the function of changing a voltage applied to the drive TFT to select the pixel. Meanwhile, the drive TFT has the function of supplying a current required for light emission. Thus, the selection TFT and the drive TFT have the different functions, and therefore, may require different characteristics.

The emission intensity of each pixel is directly controlled by the drive TFT. Therefore, variations in the TFT characteristics of the drive TFT result in variations in emission intensity, leading to defective display quality such as irregular luminance and burn-in. Therefore, pixel circuits for organic EL display apparatuses, particularly drive TFTs, are required to have not only high mobility, but also a highly uniform flowing current and high reliability.

One non-limiting, and exemplary embodiment provides an organic EL display apparatus and active matrix substrate having a feature that a plurality of oxide semiconductor TFTs having different required characteristics coexist appropriately.

In one general aspect, an organic EL display apparatus disclosed herein having a plurality of pixels arranged in a matrix, includes a substrate, and a pixel circuit provided for each of the plurality of pixels. The pixel circuit includes a plurality of oxide semiconductor TFTs supported on the substrate, the plurality of oxide semiconductor TFTs including a first oxide semiconductor TFT having a first oxide semiconductor layer and a second oxide semiconductor TFT having a second oxide semiconductor layer. The first oxide semiconductor TFT has the first oxide semiconductor layer disposed on a first insulating layer disposed on the substrate, a first gate insulating layer disposed on the first oxide semiconductor layer, a first gate electrode disposed on the first gate insulating layer, facing the first oxide semiconductor layer, and a first source electrode and a first drain electrode electrically connected to the first oxide semiconductor layer. The second oxide semiconductor TFT has a second gate electrode disposed on the substrate, a second gate insulating layer covering the second gate electrode, the second oxide semiconductor layer disposed on the second gate insulating layer, facing the second gate electrode, a second source electrode and a second drain electrode electrically connected to the second oxide semiconductor layer, and a shield electrode disposed on a second insulating layer disposed on the second oxide semiconductor layer, facing the second oxide semiconductor layer.

In one non-limiting, and exemplary embodiment, the pixel circuit includes a selection TFT, a drive TFT, and a capacitive element. The second oxide semiconductor TFT is the drive TFT.

In one non-limiting, and exemplary embodiment, the first oxide semiconductor TFT is the selection TFT.

In one non-limiting, and exemplary embodiment, a length of the second gate electrode in a channel length direction of the second oxide semiconductor TFT is greater than a length of the shield electrode in the channel length direction.

In one non-limiting, and exemplary embodiment, a fixed potential is applied to the shield electrode.

In one non-limiting, and exemplary embodiment, the fixed potential is a ground potential.

In one non-limiting, and exemplary embodiment, substantially the same potential that is applied to the second gate electrode is applied to the shield electrode.

In one non-limiting, and exemplary embodiment, the first insulating layer and the second gate insulating layer are disposed in the same layer. The first oxide semiconductor layer and the second oxide semiconductor layer are disposed in the same layer. The first gate insulating layer and the second insulating layer are disposed in the same layer. The first gate electrode and the shield electrode are disposed in the same layer. The first source electrode, the first drain electrode, the second source electrode, and the second drain electrode are disposed in the same layer.

In one non-limiting, and exemplary embodiment, the organic EL display apparatus further includes a protection layer covering the pixel circuit, a pixel electrode disposed on the protection layer and electrically connected to the pixel circuit, an organic EL layer disposed on the pixel electrode, and an upper electrode disposed on the organic EL layer.

In one non-limiting, and exemplary embodiment, the first oxide semiconductor layer and the second oxide semiconductor layer each contain an In—Ga—Zn—O semiconductor.

In one non-limiting, and exemplary embodiment, the In—Ga—Zn—O semiconductor includes a crystalline portion.

In another general aspect, an active matrix substrate disclosed herein having a display region defined by a plurality of pixel regions arranged in a matrix, and a peripheral region located around the display region, includes a substrate, and a peripheral circuit monolithically formed on the substrate in the peripheral region. The peripheral circuit includes a plurality of oxide semiconductor TFTs supported on the substrate, the plurality of oxide semiconductor TFTs including a first oxide semiconductor TFT having a first oxide semiconductor layer and a second oxide semiconductor TFT having a second oxide semiconductor layer. The first oxide semiconductor TFT has the first oxide semiconductor layer disposed on a first insulating layer disposed on the substrate, a first gate insulating layer disposed on the first oxide semiconductor layer, a first gate electrode disposed on the first gate insulating layer, facing the first oxide semiconductor layer, and a first source electrode and a first drain electrode electrically connected to the first oxide semiconductor layer. The second oxide semiconductor TFT has a second gate electrode disposed on the substrate, a second gate insulating layer covering the second gate electrode, the second oxide semiconductor layer disposed on the second gate insulating layer, facing the second gate electrode, a second source electrode and a second drain electrode electrically connected to the second oxide semiconductor layer, and a shield electrode disposed on a second insulating layer disposed on the second oxide semiconductor layer, facing the second oxide semiconductor layer.

In one non-limiting, and exemplary embodiment, a length of the second gate electrode in a channel length direction of the second oxide semiconductor TFT is greater than a length of the shield electrode in the channel length direction.

In one non-limiting, and exemplary embodiment, a fixed potential is applied to the shield electrode.

In one non-limiting, and exemplary embodiment, the fixed potential is a ground potential.

In one non-limiting, and exemplary embodiment, substantially the same potential that is applied to the second gate electrode is applied to the shield electrode.

In one non-limiting, and exemplary embodiment, the first insulating layer and the second gate insulating layer are disposed in the same layer. The first oxide semiconductor layer and the second oxide semiconductor layer are disposed in the same layer. The first gate insulating layer and the second insulating layer are disposed in the same layer. The first gate electrode and the shield electrode are disposed in the same layer. The first source electrode, the first drain electrode, the second source electrode, and the second drain electrode are disposed in the same layer.

In one non-limiting, and exemplary embodiment, the first oxide semiconductor layer and the second oxide semiconductor layer each contain an In—Ga—Zn—O semiconductor.

In one non-limiting, and exemplary embodiment, the In—Ga—Zn—O semiconductor includes a crystalline portion.

According to the above aspects, it is possible to provide an organic EL display apparatus and active matrix substrate having a configuration in which a plurality of oxide semiconductor TFTs having different required characteristics coexist appropriately.

### BRIEF DESCRIPTION OF THE DRAWINGS

FIG. 1 is a plan view schematically showing an organic EL display apparatus 100.

FIG. 2 is an equivalent circuit diagram showing a pixel circuit Pc of the organic EL display apparatus 100.

FIG. 3 is a cross-sectional view schematically showing the organic EL display apparatus 100.

FIGS. 4A and 4B are graphs showing gate voltage-drain current (Vg-Id) characteristics of a selection TFT 10 and a drive TFT 20, respectively.

FIGS. 5A and 5B are graphs showing drain voltage-drain current (Vd-Id) characteristics of the selection TFT 10 and the drive TFT 20, respectively.

FIG. 6 is a graph showing gate voltage-drain current characteristics of the drive TFT 20 that are obtained when a fixed potential applied to a shield electrode 26 of the drive TFT 20 is changed.

FIG. 7 is a cross-sectional view schematically showing the organic EL display apparatus 100.

FIGS. 8A-8D are cross-sectional views schematically showing steps in a production process of the organic EL display apparatus 100.

FIGS. 9A-9C are cross-sectional views schematically showing steps in the production process of the organic EL display apparatus 100.

FIGS. 10A-10C are cross-sectional views schematically showing steps in the production process of the organic EL display apparatus 100.

FIG. 11 is a diagram for explaining that the resistance values of a first oxide semiconductor layer 13 and a second oxide semiconductor 23 can be changed in a stepwise manner by a plasma treatment.

FIG. 12 is an equivalent circuit diagram showing another example pixel circuit Pc of the organic EL display apparatus 100.

FIG. 13 is a plan view schematically showing an active matrix substrate 200 according to an embodiment of the present invention.

FIG. 14 is a cross-sectional view showing a pixel circuit 900Pc of a bottom-emission organic EL display apparatus.

### DETAILED DESCRIPTION

Embodiments of the present invention will now be described with reference to the accompanying drawings. Note that the present invention is in no way intended to be limited to the embodiments described below.

### First Embodiment

An organic EL display apparatus 100 according to this embodiment will be described with reference to FIG. 1. FIG. 1 is a plan view schematically showing the organic EL display apparatus 100.

As shown in FIG. 1, the organic EL display apparatus 100 has a plurality of pixels P arranged in a matrix. The pixels P typically include red pixels for displaying red, green pixels for displaying green, and blue pixels for displaying blue.

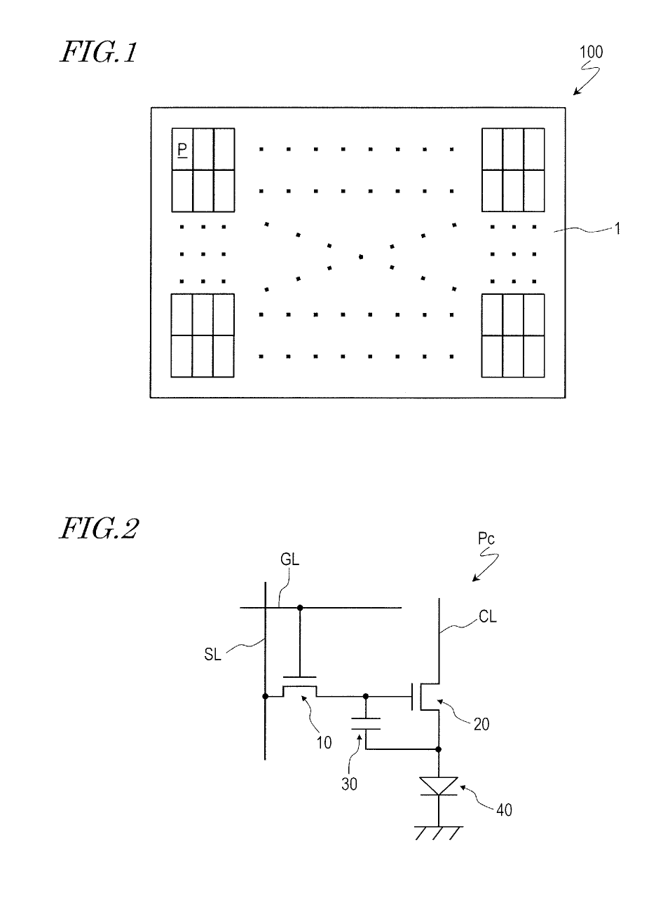

The organic EL display apparatus 100 also includes a substrate 1, and pixel circuits (not shown in FIG. 1), one for each pixel P. FIG. 2 shows an example pixel circuit.

The pixel circuit Pc of FIG. 2 includes a selection TFT 10, a drive TFT 20, and a capacitive element (storage capacitor) 30. The selection TFT 10 and the drive TFT 20 are supported by the substrate 1, and are each an oxide semiconductor TFT having an oxide semiconductor layer.

The gate electrode of the selection TFT 10 is connected to a gate line GL. The source electrode of the selection TFT 10 is connected to a source line SL. The drain electrode of the selection TFT 10 is connected to the gate electrode of the drive TFT 20 and the capacitive element 30. The source electrode of the drive TFT 20 is connected to a current supply line CL. The drain electrode of the drive TFT 20 is connected to an organic light emitting diode (OLED) 40.

When an on-signal is supplied from the gate line GL to the gate electrode of the selection TFT 10, the selection TFT 10 is turned on, so that a signal voltage (corresponding to a desired luminance of light emitted by the OLED 40) is applied from the source line SL through the selection TFT 10 to the capacitive element 30 and the gate electrode of the drive TFT 20. When the drive TFT 20 is turned on by the signal voltage, a current flows from the current supply line CL through the drive TFT 20 to the OLED 40, which then emits light.

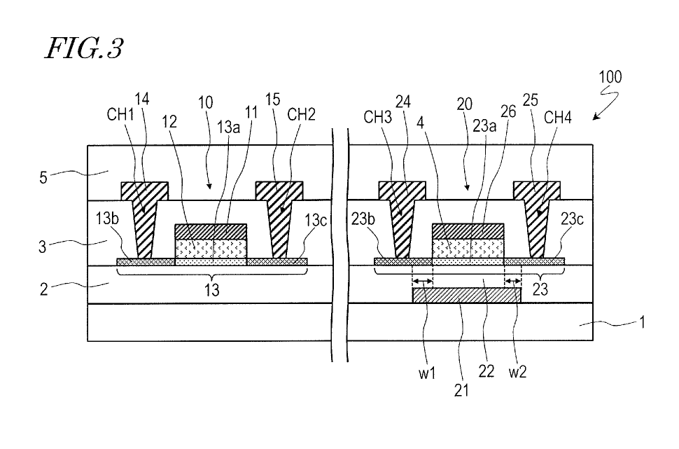

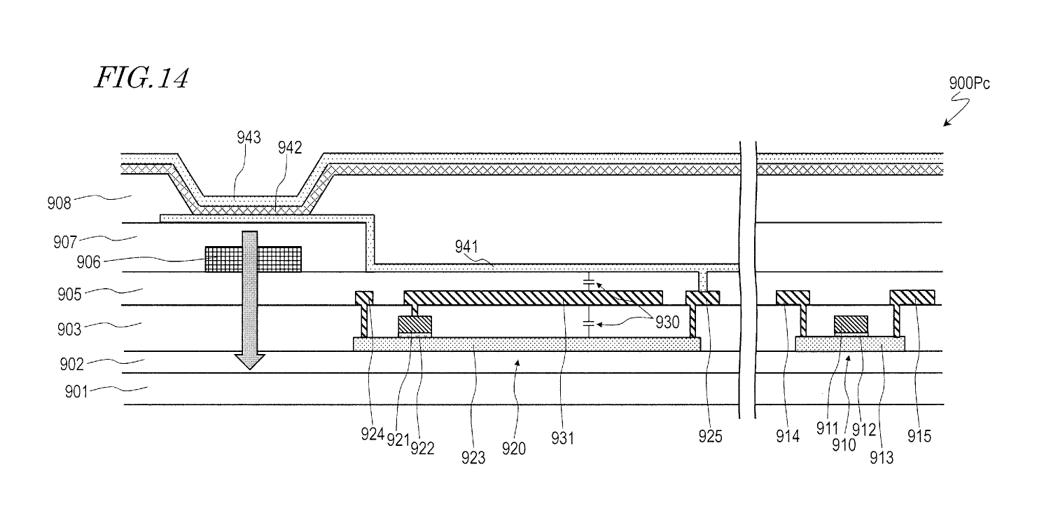

In the pixel circuit 900Pc of FIG. 14, the selection TFT 910 and the drive TFT 920 both have a top-gate structure (i.e., the same structure). In contrast to this, in the pixel circuit Pc of this embodiment, the selection TFT and the drive TFT 20 have different structures. The structures of the selection TFT 10 and the drive TFT 20 will now be described with reference to FIG. 3. FIG. 3 is a cross-sectional view schematically showing a region of the organic EL display apparatus 100 in which the selection TFT 10 and the drive TFT 20 are formed. Note that in FIG. 3, no constituent elements disposed above a protection layer 5 are shown. In other words, FIG. 3 shows an active matrix substrate of the organic EL display apparatus 100 that functions as a backplane.

The selection TFT 10 has a first gate electrode 11, a first gate insulating layer 12, a first oxide semiconductor layer 13, a first source electrode 14, and a first drain electrode 15.

The first oxide semiconductor layer 13 is disposed on a first insulating layer 2 disposed on the substrate 1. The first oxide semiconductor layer 13 includes a channel region 13a, and a source region 13b and a drain region 13c that are located on opposite sides of the channel region 13a. In the source region 13b and the drain region 13c, the resistance of the oxide semiconductor has been reduced. In the channel region 13a, the resistance of the oxide semiconductor has not been reduced.

The first gate insulating layer 12 is disposed on the first oxide semiconductor layer 13. In the example of FIG. 3, the first gate insulating layer 12 overlaps the channel region 13a of the first oxide semiconductor layer 13.

The first gate electrode 11 is disposed on the first gate insulating layer 12. The first gate electrode 11 faces the first oxide semiconductor layer 13. More specifically, the first gate electrode 11 faces the channel region 13a of the oxide semiconductor layer 13.

An interlayer insulating layer 3 is provided to cover the first oxide semiconductor layer 13 and the first gate electrode 11. The first source electrode 14 and the first drain electrode 15 are disposed on the interlayer insulating layer 3. The first source electrode 14 and the first drain electrode 15 are electrically connected to the first oxide semiconductor layer 13. Specifically, the first source electrode 14 and the first drain electrode 15 are connected to the source region 13b and the drain region 13c, respectively, of the first oxide semiconductor layer 13 through a first contact hole CH1 and a second contact hole CH2, respectively, that are formed in the interlayer insulating layer 3.

Thus, the selection TFT 10 has a top-gate structure.

The drive TFT 20 has a second gate electrode 21, a second gate insulating layer 22, a second oxide semiconductor layer 23, a second source electrode 24, and a second drain electrode 25.

The second gate electrode 21 is disposed on the substrate 1.

The second gate insulating layer 22 is provided to cover the second gate electrode 21. The second gate insulating layer 22 is formed of the same insulating film of which the first insulating layer 2 is formed. In other words, the first insulating layer 2 and the second gate insulating layer 22 are disposed in the same layer. More specifically, the first insulating layer 2 is provided in not only a region where the selection TFT 10 is provided, but also a region where the drive TFT 20 is provided. A portion of the first insulating layer 2 that covers the second gate electrode 21 (i.e., overlaps the second gate electrode 21) functions as the second gate insulating layer 22.

The second oxide semiconductor layer 23 is disposed on the second gate insulating layer 22. The second oxide semiconductor layer 23 faces the second gate electrode 21. The second oxide semiconductor layer 23 includes a channel region 23a, and a source region 23b and a drain region 23c that are located on opposite sides of the channel region 23a. In the source region 23b and the drain region 23c, the resistance of the oxide semiconductor has been reduced. In the channel region 23a, the resistance of the oxide semiconductor has not been reduced. The second oxide semiconductor layer 23 is formed of the same oxide semiconductor film of which the first oxide semiconductor layer 13 is formed. In other words, the first oxide semiconductor layer 13 and the second oxide semiconductor layer 23 are disposed in the same layer.

The interlayer insulating layer 3 covers the second oxide semiconductor layer 23. The second source electrode 24 and the second drain electrode 25 are disposed on the interlayer insulating layer 3. The second source electrode and the second drain electrode 25 are electrically connected to the second oxide semiconductor layer 23. Specifically, the second source electrode 24 and the second drain electrode 25 are connected to the source region 23b and the drain region 23c, respectively, of the second oxide semiconductor layer 23 through a third contact hole CH3 and a fourth contact hole CH4, respectively, that are formed in the interlayer insulating layer 3. The second source electrode 24 and the second drain electrode 25 are formed of the same conductive film of which the first source electrode 14 and the first drain electrode 15 are formed. In other words, the first source electrode 14, the first drain electrode 15, the second source electrode 24, and the second drain electrode 25 are disposed in the same layer.

Thus, the drive TFT 20 has a bottom-gate structure. The drive TFT 20 further has a shield electrode 26. The shield electrode 26 is disposed on a second insulating layer 4 disposed on the second oxide semiconductor layer 23, facing the second oxide semiconductor layer 23. More specifically, the second insulating layer 4 overlaps the channel region 23a of the second oxide semiconductor layer 23, and the shield electrode 26 faces the channel region 23a of the second oxide semiconductor layer 23. The second insulating layer 4 is formed of the same insulating film of which the first gate insulating layer 12 is formed. In other words, the first gate insulating layer 12 and the second insulating layer 4 are disposed in the same layer. The shield electrode 26 is formed of the same conductive film of which the first gate electrode 11 is formed. In other words, the first gate electrode 11 and the shield electrode 26 are disposed in the same layer. Here, a fixed potential (e.g., a ground potential) is applied to the shield electrode 26.

In the example of FIG. 3, a length of the second gate electrode 21 in a channel length direction of the drive TFT 20 is greater than a length of the shield electrode 26 in the channel length direction. Therefore, the second gate electrode 21 overlaps not only the channel region 23a of the second oxide semiconductor layer 23, but also a portion of the source region 23b and a portion of the drain region 23c (i.e., portions of the resistance-reduced regions).

A protection layer 5 is provided to cover the pixel circuit Pc including the selection TFT 10 and the drive TFT 20, i.e., the entire pixel circuit Pc. A pixel electrode, etc. (not shown), are provided on the protection layer 5. Although FIG. 3 does not explicitly show the capacitive element 30, the capacitive element 30 may be configured by a pair of electrodes, and an insulating layer (dielectric layer) interposed therebetween. The pair of electrodes included in the capacitive element 30 are, for example, a conductive layer electrically connected to the second gate electrode 21 of the drive TFT 20 (i.e., the first drain electrode 15 of the selection TFT 10), and a conductive layer electrically connected to the second drain electrode 25 of the drive TFT 20.

As described above, in the organic EL display apparatus 100 of this embodiment, the oxide semiconductor TFT 10 having the top-gate structure and the oxide semiconductor TFT 20 having the bottom-gate structure are separately formed in the pixel circuit Pc. Thus, a plurality of oxide semiconductor TFTs having different required characteristics (here, the selection TFT 10 and the drive TFT 20) can coexist appropriately. The oxide semiconductor TFT 20 having the bottom-gate structure has the shield electrode 26. The shield electrode 26 facing the second oxide semiconductor layer 23 can have the effect of blocking external electric field during operation of the TFT. The electric field blocking effect of the shield electrode 26 can increase the uniformity of a current flow caused by the drive TFT 20, and improve the reliability of the drive TFT 20. Thus, preferable characteristics of the drive TFT 20 can be achieved. Advantages that are obtained by the configuration of this embodiment will now be described in greater detail.

In the above configuration, the electrodes and insulating layers of the selection TFT 10 and the drive TFT 20 have the following relationships.

(1) The first insulating layer 2 and the second gate insulating layer 22 are disposed in the same layer.

(2) The first oxide semiconductor layer 13 and the second oxide semiconductor layer 23 are disposed in the same layer.

(3) The first gate insulating layer 12 and the second insulating layer 4 are disposed in the same layer.

(4) The first gate electrode 11 and the shield electrode 26 are disposed in the same layer.

(5) The first source electrode 14, the first drain electrode 15, the second source electrode 24, and the second drain electrode 25 are disposed in the same layer.

Therefore, compared to the conventional configuration in which all oxide semiconductor TFTs in a pixel circuit have a top-gate structure (FIG. 14), the production of the pixel circuit Pc of this embodiment additionally includes only a step of forming the second gate electrode 21 between the substrate 1 and the second gate insulating layer 22, in order to achieve the configuration in which the selection TFT 10 having the top-gate structure and the drive TFT 20 having the bottom-gate structure coexist.

As described below, the selection TFT 10 may have a self-aligned top-gate structure that is formed by performing a resistance reduction treatment on the oxide semiconductor film using the first gate electrode 11 as a mask. Therefore, the resistance reduction and the reduction of load capacitance of the TFT can advantageously be achieved by a relatively low-cost process.

In addition, the field blocking effect of the shield electrode 26 of the drive TFT 20 can improve the uniformity and reliability of the TFT. Note that during the production, the shield electrode 26 functions as a mask in the resistance reduction treatment for the oxide semiconductor. The shield electrode 26 also has the effect of reducing the concentration of electric field to the drain end and thereby improving the source-drain breakdown voltage.

The length of the second gate electrode 21 in the channel length direction of the drive TFT 20 is greater than the length of the shield electrode 26 in the channel length direction. Therefore, the second gate electrode 21 overlaps not only the channel region 23a of the second oxide semiconductor layer 23, but also a portion of the source region 23b and a portion of the drain region 23c, i.e., the drive TFT 20 has the so-called gate-overlapped drain (GOLD) structure. Therefore, the reliability is further improved.

The greater length of the second gate electrode 21 (the second gate electrode 21 overlaps not only the channel region 23a, but also a portion of the source region 23b and a portion of the drain region 23c) means that the actual channel length is greater than the actual length of the channel region 23a. A change in channel length affects TFT characteristics.

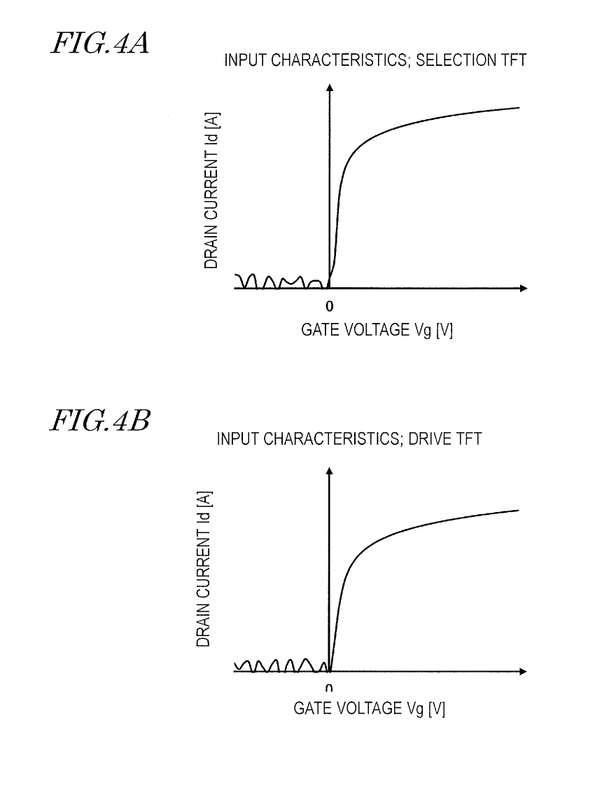

FIGS. 4A and 4B show input characteristics of the selection TFT 10 and the drive TFT 20. FIGS. 4A and 4B are graphs showing gate voltage-drain current (Vg-Id) characteristics. Comparison between FIG. 4A and FIG. 4B shows that the selection TFT 10 has a greater on-state drain current (on-current) Ion and a smaller S factor (subthreshold coefficient) than those of the drive TFT 20. Therefore, it can be seen that the on-current Ion decreases and the S factor becomes worse with an increase in the channel length.

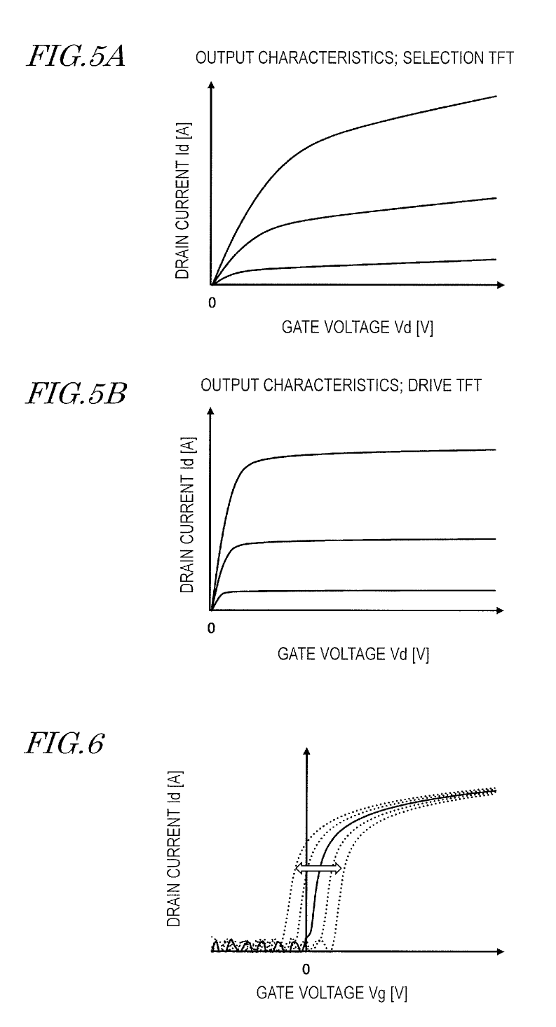

FIGS. 5A and 5B show output characteristics of the selection TFT 10 and the drive TFT 20. FIGS. 5A and 5B are graphs showing drain voltage-drain current (Vd-Id) characteristics. Comparison between FIG. 5A and FIG. 5B shows that the drive TFT 20 has smaller current changes with respect to voltage changes than those of the selection TFT 10 (saturation properties are improved). Therefore, it can be seen that as the channel length increases, the uniformity of a flowing current increases, and therefore, required performance of the drive TFT 20 is more easily satisfied.

Here, the potential applied to the shield electrode 26 will be described.

As described above, the fixed potential applied to the shield electrode 26 is, for example, the ground potential (i.e., 0 V). By fixing the potential of the shield electrode 26 to the ground potential, drive stability is improved.

Alternatively, the potential of the shield electrode 26 may be fixed to potentials other than the ground potential. FIG. 6 shows example gate voltage-drain current characteristics of the drive TFT 20 that are obtained when the fixed potential Vsh applied to the shield electrode 26 is changed. As can be seen from FIG. 6, the threshold voltage of the drive TFT 20 can be controlled by adjusting the fixed potential applied to the shield electrode 26. Therefore, for example, the consumed power of the organic EL display apparatus 100 can be reduced.

Alternatively, substantially the same potential that is applied to the second gate electrode 21 may be applied to the shield electrode 26. As a result, the so-called double-gate drive can be performed, and therefore, the on-current Ion can be increased, whereby driving capability can be further improved.

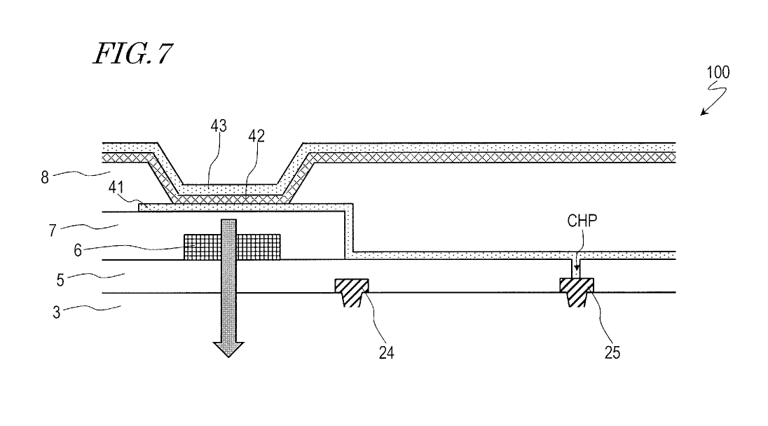

FIG. 7 shows an example arrangement of pixel electrodes, etc., that are disposed above the protection layer 5. In the example of FIG. 7, a color filter layer 6 is disposed on the protection layer 5, and a planarization layer 7 is provided to cover the color filter layer 6. A pixel electrode 41 is disposed on the planarization layer 7. The pixel electrode 41 is provided for each pixel P, and is electrically connected to the pixel circuit Pc. More specifically, the pixel electrode 41 is electrically connected to the second drain electrode 25 of the drive TFT 20, and functions as, for example, an anode. In the example of FIG. 7, the pixel electrode 41 is extended to a region above the drive TFT 20 where the planarization layer 7 is not formed, and is connected to the second drain electrode 25 through a pixel contact hole CHP formed in the protection layer 5.

A bank 8 formed of an insulating material is disposed between adjacent pixels. The bank 8 covers a portion of the pixel electrode 41.

An organic EL layer 42 is disposed on the pixel electrode 41 of each pixel P. The organic EL layer 42 has a multilayer structure including a plurality of layers formed of an organic semiconductor material. The multilayer structure includes, for example, a hole injection layer, a hole transport layer, a light emission layer, an electron transport layer, and an electron injection layer in that order with the hole injection layer closest to the pixel electrode 41.

An upper electrode 43 is disposed on the organic EL layer 42. The upper electrode 43 continuously spreads throughout the display region, and functions as, for example, a cathode.

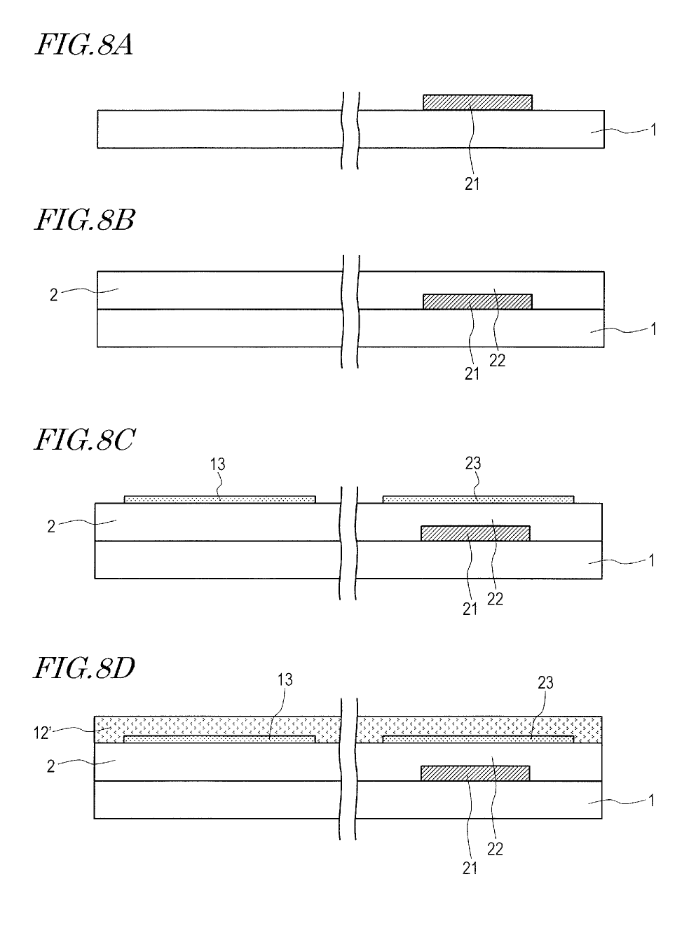

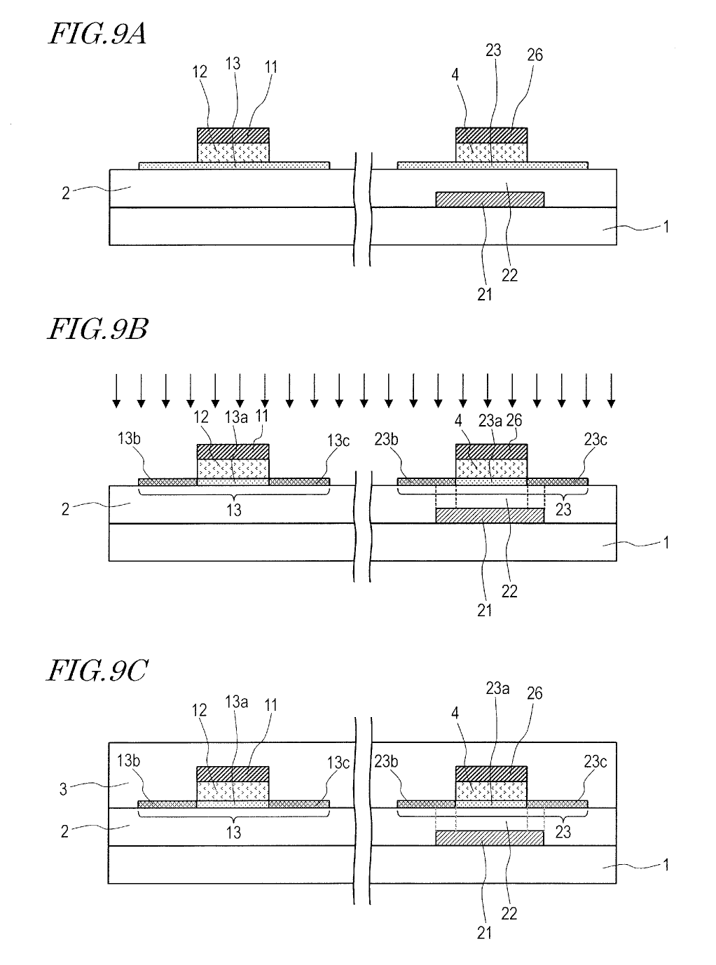

Next, a production method for the organic EL display apparatus 100 of this embodiment will be described with reference to FIGS. 8A-8D, 9A-9C, and 10A-10C. FIGS. 8A-8D, 9A-9C, and 10A-10C are cross-sectional views schematically showing steps in a production process of the organic EL display apparatus 100.

Initially, as shown in FIG. 8A, the second gate electrode 21 is formed on the substrate 1. Specifically, for example, the second gate electrode 21 can be formed by depositing a conductive film on the substrate 1 by sputtering, and thereafter, patterning the conductive film by a photolithography process and dry etching. The substrate 1 can, for example, be a glass substrate, silicon substrate, or heat-resistant plastic substrate (resin substrate). Examples of a material for the plastic substrate (resin substrate) include polyethylene terephthalate (PET), polyethylene naphthalate (PEN), polyether sulfones (PESs), acrylic resins, and polyimides. Examples of a material for the conductive film include metals such as aluminum (Al), tungsten (W), molybdenum (Mo), tantalum (Ta), chromium (Cr), titanium (Ti), and copper (Cu), alloys thereof, and metal nitrides thereof. These materials can be used as appropriate. The conductive film may be formed by layering a plurality of layers formed of these materials. Here, as the conductive film, formed is a multilayer film (MoN/Al film) including a MoN layer having a thickness of 50 nm as an upper layer and an Al layer having a thickness of 350 nm as a lower layer.

Next, as shown in FIG. 8B, the first insulating layer 2 is formed on the substrate 1 to cover the second gate electrode 21. The first insulating layer 2 here formed includes a portion that functions as the second gate insulating layer 22. The first insulating layer 2 is, for example, a silicon oxide (SiOₓ) layer, silicon nitride (SiNₓ) layer, silicon oxynitride (SiOₓN_{y}; x>y) layer, silicon nitroxide (SiNₓO_{y}; x>y) layer, etc. Here, as the first insulating layer 2, a SiO₂ layer having a thickness of 375 nm is formed by CVD.

Next, as shown in FIG. 8C, the first oxide semiconductor layer 13 and the second oxide semiconductor layer 23 are formed on the first insulating layer 2. Specifically, for example, the first oxide semiconductor layer 13 and the second oxide semiconductor layer 23 can be formed by depositing an oxide semiconductor film having a thickness of 30-100 nm on the first insulating layer 2 by sputtering, and thereafter, patterning the oxide semiconductor film by a photolithography process and etching. Specific materials, etc., for the first oxide semiconductor layer 13 and the second oxide semiconductor layer 23 are described in detail below.

Next, as shown in FIG. 8D, an insulating film 12′ is formed to cover the first oxide semiconductor layer 13 and the second oxide semiconductor layer 23. The insulating film 12′ here formed includes portions that are to serve as the first gate insulating layer 12 and the second insulating layer 4. If the insulating film 12′ has a thickness smaller than that of the first insulating layer 2, the on-current Ion is easily increased. Here, as the insulating film 12′, a SiO₂ layer having a thickness of 150 nm is formed by CVD. Thereafter, a contact hole (not shown) for electrically connecting the second gate electrode 21 to another conductive layer is formed at a predetermined location of the insulating film 12′.

Next, as shown in FIG. 9A, the first gate electrode 11 and the shield electrode 26 are formed on the insulating film 12′. Specifically, for example, the first gate electrode 11 and the shield electrode 26 can be formed by depositing a conductive film on the insulating film 12′ by sputtering, and thereafter, patterning the conductive film by a photolithography process and dry etching. Examples of a material for the conductive film include metals such as aluminum (Al), tungsten (W), molybdenum (Mo), tantalum (Ta), chromium (Cr), titanium (Ti), and copper (Cu), alloys thereof, and metal nitrides thereof. These materials can be used as appropriate. The conductive film may be formed by layering a plurality of layers formed of these materials. Here, as the conductive film, formed is a multilayer film (MoN/Al film) including a MoN layer having a thickness of 50 nm as an upper layer and an Al layer having a thickness of 350 nm as a lower layer. At the same time that the first gate electrode 11 and the shield electrode 26 are formed, the insulating film 12′ is etched so that portions of the insulating film 12′ that are not covered by the first gate electrode 11 or the shield electrode 26 are removed. Portions of the insulating film 12′ that have not been removed (i.e., portions thereof covered by the first gate electrode 11 and the shield electrode 26) are the first gate insulating layer 12 and the second insulating layer 4.

Next, as shown in FIG. 9B, the entire surface of the substrate 1 is plasma-treated. Examples of the plasma treatment include a hydrogen plasma treatment and He plasma treatment. In the plasma treatment, the first gate electrode serves as a mask, and therefore, the resistances of regions of the first oxide semiconductor layer 13 that are not covered by the first gate electrode 11 are reduced. The resultant regions are the source region 13b and the drain region 13c. The resistance of a region of the first oxide semiconductor layer 13 that is covered by the first gate electrode 11 is not reduced. This region is the channel region 13a. Similarly, in the plasma treatment, the shield electrode 26 serves as a mask, and therefore, the resistances of regions of the second oxide semiconductor layer 23 that are not covered by the shield electrode 26 are reduced. The resultant regions are the source region 23b and the drain region 23c. The resistance of a region of the second oxide semiconductor layer 23 that is covered by the shield electrode 26 is not reduced. This region is the channel region 23a.

Next, as shown in FIG. 9C, the interlayer insulating layer 3 is formed to cover the first gate electrode 11, the shield electrode 26, etc. The interlayer insulating layer 3 is, for example, a silicon oxide (SiO₂) layer or silicon nitride (SiNₓ) layer. The interlayer insulating layer 3 may be configured by layering these layers. The interlayer insulating layer 3 can be formed by, for example, CVD. Note that if the silicon nitride layer is formed to be in contact with exposed portions of the surfaces of the first oxide semiconductor layer 13 and the second oxide semiconductor layer 23, the resistance of the oxide semiconductor of those portions is reduced, whereby a self-aligned structure can be formed. Here, as the interlayer insulating layer 3, a silicon nitride (SiNₓ) layer having a thickness of 100 nm and a silicon oxide (SiO₂) layer having a thickness of 300 nm are successively formed.

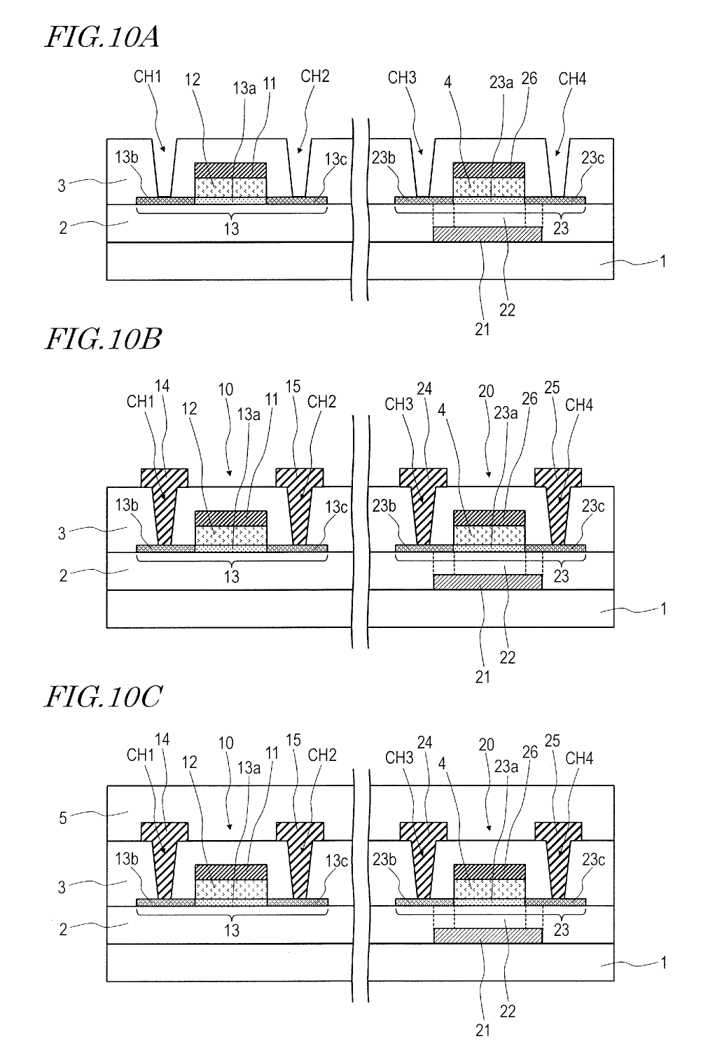

Next, as shown in FIG. 10A, the first, second, third, and fourth contact holes CH1, CH2, CH3, and CH4 are formed in the interlayer insulating layer 3 by a photolithography process and etching.

Next, as shown in FIG. 10B, the first source electrode 14, the first drain electrode 15, the second source electrode 24, and the second drain electrode 25 are formed on the interlayer insulating layer 3. Specifically, for example, the first source electrode 14, etc., can be formed by depositing a conductive film on the interlayer insulating layer 3 by sputtering, and thereafter, patterning the conductive film by a photolithography process and dry etching. Examples of a material for the conductive film include aluminum (Al), molybdenum (Mo), tantalum (Ta), chromium (Cr), titanium (Ti), and gold (Au). These materials can be used as appropriate. The conductive film may be formed by layering a plurality of layers formed of these materials. Here, as the conductive film, formed is a multilayer film (Ti/Al/Ti film) including a Ti layer having a thickness of 50 nm as an upper layer, an Al layer having a thickness of 300 nm as a middle layer, and a Ti layer having a thickness of 30 nm as a lower layer.

Next, as shown in FIG. 10C, the protection layer 5 is formed to cover the selection TFT 10 and the drive TFT 20. Thereafter, the color filter layer 6, the planarization layer 7, the pixel electrode 41, etc., are formed on the protection layer 5. Thus, the organic EL display apparatus 100 is completed.

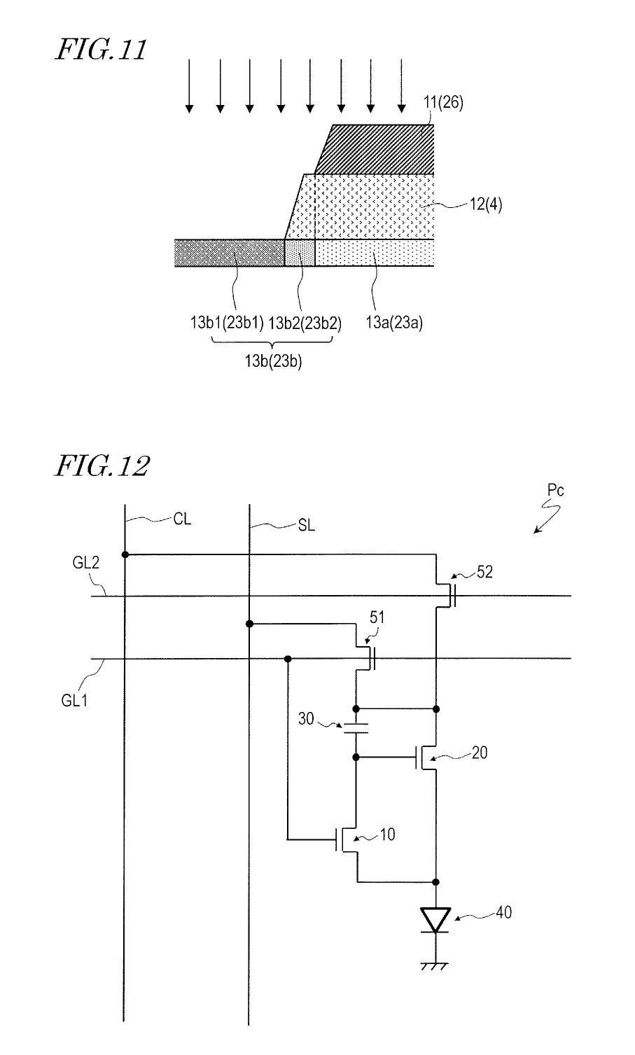

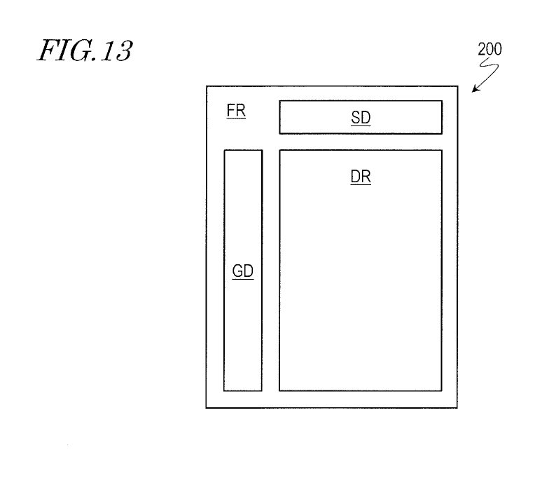

Note that when the resistances of portions of the first oxide semiconductor layer 13 and the second oxide semiconductor 23 are reduced by a plasma treatment, then if, as shown in FIG. 11, the first gate insulating layer 12 and the first gate electrode 11, and the second insulating layer and the shield electrode 26, have a tapered end, the resistance values of the first oxide semiconductor layer 13 and the second oxide semiconductor 23 can be caused to change in a stepwise manner. In the example of FIG. 11, the source region 13b (23b) includes a first resistance-reduced region 13b1 (23b1), and a second resistance-reduced region 13b2 (23b2) located between the first resistance-reduced region 13b1 (23b1) and the channel region 13a (23a). The first resistance-reduced region 13b1 (23b1) has a resistance value smaller than that of the channel region 13a (23a). The second resistance-reduced region 13b2 (23b2) has a resistance value that is smaller than that of the channel region 13a (23a) and greater than that of the first resistance-reduced region 13b1 (23b1). In the drain region 13c (23c), the resistance value can be similarly caused to change in a stepwise manner.

In order to more reliably satisfy the relationship that the length of the second gate electrode 21 in the channel length direction (i.e., a channel length defined by the second gate electrode 21) is greater than the length of the shield electrode 26 in the channel length direction (i.e., a channel length defined by the shield electrode 26), an overlap width w1 (see FIG. 3) of the second gate electrode 21 with respect to the source region 23b, and an overlap width w2 (see FIG. 3) of the second gate electrode 21 with respect to the drain region 23c, are each preferably set to, for example, about 1-2 μm, taking into account the accuracy of processing, etc.

Although, in this embodiment, the bottom-emission configuration (FIG. 7) is illustrated, an organic EL display apparatus according to an embodiment of the present invention is not limited to the bottom-emission type, and may be of the top-emission type. An organic EL display apparatus according to an embodiment of the present invention may be of a vapor deposition type that the organic EL layer is formed by vapor deposition, or a printing type that the organic EL layer is formed by a printing method.

The pixel circuit Pc is not limited to the example of FIG. 2. The pixel circuit Pc may include three or more oxide semiconductor TFTs, and may include a portion that functions as a compensation circuit for compensating for variations in luminance.

FIG. 12 shows another example of the pixel circuit Pc. In the example of FIG. 12, the pixel circuit Pc includes a selection TFT 10, a drive TFT 20, a capacitive element 30, and an OLED 40, and in addition, a first current switching TFT 51 and a second current switching TFT 52.

The gate electrode of the drive TFT 20 is connected to the source electrode of the selection TFT 10 and one of a pair of electrodes included in the capacitive element 30. The source electrode of the drive TFT 20 is connected to the drain electrodes of the first and second current switching TFTs 51 and 52. The drain electrode of the drive TFT 20 is connected to the drain electrode of the selection TFT 10 and the OLED 40.

The gate electrode of the selection TFT 10 is connected to a first gate line GL1. The source electrode of the selection TFT 10 is connected to the gate electrode of the drive TFT 20. The drain electrode of the selection TFT 10 is connected to the drain electrode of the drive TFT 20.

The gate electrode of the first current switching TFT 51 is connected to the first gate line GL1. The source electrode of the first current switching TFT 51 is connected to a source line SL. The drain electrode of the first current switching TFT 51 is connected to the source electrode of the drive TFT 20, and the other of the pair of electrodes included in the capacitive element 30.

The gate electrode of the second current switching TFT 52 is connected to a second gate line GL2. The source electrode of the second current switching TFT 52 is connected to a current supply line CL. The drain electrode of the second current switching TFT 52 is connected to the source electrode of the drive TFT 20.

The pixel circuit Pc of FIG. 12 operates as follows.

Initially, when the selection TFT 10 and the first current switching TFT 51 are selected and turned on by the first gate line GL1, the gate electrode and drain electrode of the drive TFT 20 are connected together, i.e., a diode connection is established therebetween. Therefore, the capacitive element 30 is charged by a voltage corresponding to a data current I_{DATA} supplied from the source line SL.

Next, when the selection TFT 10 and the first current switching TFT 51 are turned off, and the second current switching TFT 52 is selected and turned on by the second gate line GL2, a current is supplied from the current supply line CL through the second current switching TFT 52 and the drive TFT 20 (in the on-state due to the voltage of the charged capacitive element 30) to the OLED 40, which then emits light.

The first current switching TFT 51 and the second current switching TFT 52 each preferably have a top-gate structure as with the selection TFT 10.

### Second Embodiment

In the first embodiment, the organic EL display apparatus 100 and an active matrix substrate for use therein have been illustrated. Embodiments of the present invention are not limited to these.

FIG. 13 shows an active matrix substrate 200 according to this embodiment. The active matrix substrate 200 is used for a liquid crystal display apparatus.

As shown in FIG. 13, the active matrix substrate 200 has a display region DR and a peripheral region FR. The display region DR is defined by a plurality of pixel regions (regions corresponding to pixels) arranged in a matrix. The peripheral region FR is located around the display region DR, and is also referred to as a “frame region.”

The active matrix substrate 200 includes a substrate 1, a gate driver (gate line drive circuit) GD provided in the peripheral region FR, and a source driver (source line drive circuit) SD.

In this embodiment, the gate driver GD is monolithically formed on the substrate 1. In other words, the active matrix substrate 200 of this embodiment includes a peripheral circuit that is monolithically formed in the peripheral region FR. The monolithic formation of a peripheral circuit on the substrate 1 allows a reduction in cost and narrowing of the frame (a reduction in the peripheral region FR). Therefore, the active matrix substrate 200 can preferably be used in a liquid crystal display apparatus for the high-definition display of a smartphone, etc.

The gate driver GD includes a plurality of oxide semiconductor TFTs supported by the substrate 1. The oxide semiconductor TFTs each include a first oxide semiconductor TFT that has a top-gate structure as with the selection TFT 10 of the first embodiment, and a second oxide semiconductor TFT that has a bottom-gate structure and includes a shield electrode 26 as with the drive TFT 20 of the first embodiment.

Such a configuration allows oxide semiconductor TFTs having different required characteristics to coexist in the gate driver GD. For example, a buffer TFT, etc., characteristics of which are likely to deteriorate due to a high applied voltage, may be adapted to have a shield-electrode bottom-gate structure (i.e., the first oxide semiconductor TFT), whereby high reliability can be ensured. A logic TFT, etc., which is required to be driven at high speed, may be adapted to have a top-gate structure (i.e., the second oxide semiconductor TFT), whereby a low load capacitance (noise reduction) can be achieved.

Although the monolithic formation of the gate driver GD has herein been illustrated, the source driver SD may be monolithically formed instead of or in addition to the gate driver GD.

[Oxide Semiconductor]

The oxide semiconductor contained in each of the first oxide semiconductor layer 13 and the second oxide semiconductor 23 (hereinafter simply referred to as the “oxide semiconductor layer”) may be either an amorphous oxide semiconductor or a crystalline oxide semiconductor having a crystalline portion. Examples of the crystalline oxide semiconductor include polycrystalline oxide semiconductors, microcrystalline oxide semiconductors, and crystalline oxide semiconductors whose c-axis is oriented substantially perpendicularly to the layer surface.

The oxide semiconductor layer may have a multilayer structure including two or more layers. In the case where the oxide semiconductor layer has a multilayer structure, the oxide semiconductor layer may include an amorphous oxide semiconductor layer and a crystalline oxide semiconductor layer. Alternatively, the oxide semiconductor layer may include a plurality of crystalline oxide semiconductor layers having different crystal structures. Alternatively, the oxide semiconductor layer may include a plurality of amorphous oxide semiconductor layers.

Materials, structures, and film formation methods for amorphous oxide semiconductors and the above crystalline oxide semiconductors, and the configuration of the oxide semiconductor layer having a multilayer structure, are described in, for example, Japanese Laid-Open Patent Publication No. 2014-007399, the entire contents of which are hereby incorporated by reference.

The oxide semiconductor layer may, for example, contain at least one metal element of In, Ga, and Zn. In this embodiment, the oxide semiconductor layer may contain, for example, an In—Ga—Zn—O semiconductor (e.g., indium gallium zinc oxide). Here, the In—Ga—Zn—O semiconductor is a ternary oxide of In (indium), Ga (gallium), and Zn (zinc). The proportions (composition ratio) of In, Ga, and Zn in the In—Ga—Zn—O semiconductor are not particularly limited. Examples of the composition ratio include In:Ga:Zn=2:2:1, In:Ga:Zn=1:1:1, and In:Ga:Zn=1:1:2. Such an oxide semiconductor layer may be formed of an oxide semiconductor film containing the In—Ga—Zn—O semiconductor.

The In—Ga—Zn—O semiconductor may be either amorphous or crystalline. The crystalline In—Ga—Zn—O semiconductor is preferably one whose c-axis is oriented substantially perpendicularly to the layer surface.

Note that the crystal structure of the crystalline In—Ga—Zn—O semiconductor is described in, for example, Japanese Laid-Open Patent Publication No. 2014-007399 above, Japanese Laid-Open Patent Publication No. 2012-134475, Japanese Laid-Open Patent Publication No. 2014-209727, etc. The entire contents of Japanese Laid-Open Patent Publication Nos. 2012-134475 and 2014-209727 are hereby incorporated by reference. A TFT having the In—Ga—Zn—O semiconductor layer has a high mobility (more than 20 times as high as that of an a-SiTFT) and a low leakage current (less than one hundredth of that of an a-SiTFT), and therefore, is preferably used as a drive TFT (e.g., a TFT included in a drive circuit provided on the same substrate on which a display region including a plurality of pixels is provided, around the display region) and a pixel TFT (a TFT provided at a pixel).

The oxide semiconductor layer may contain other oxide semiconductors instead of the In—Ga—Zn—O semiconductor. For example, the oxide semiconductor layer may contain an In—Sn—Zn—O semiconductor (e.g., In₂O₃—SnO₂—ZnO; InSnZnO). The In—Sn—Zn—O semiconductor is a ternary oxide of In (indium), Sn (tin), and Zn (zinc). Alternatively, the oxide semiconductor layer may contain In—Al—Zn—O semiconductors, In—Al—Sn—Zn—O semiconductors, Zn—O semiconductors, In—Zn—O semiconductors, Zn—Ti—O semiconductors, Cd—Ge—O semiconductors, Cd—Pb—O semiconductors, CdO (cadmium oxide), Mg—Zn—O semiconductors, In—Ga—Sn—O semiconductors, In—Ga—O semiconductors, Zr—In—Zn—O semiconductors, Hf—In—Zn—O semiconductors, Al—Ga—Zn—O semiconductors, Ga—Zn—O semiconductors, In—Ga—Zn—Sn—O semiconductors, InGaO₃(ZnO)₅, magnesium zinc oxide (MgₓZn_{1 x}O), cadmium zinc oxide (CdₓZn_{1 x}O), etc. The Zn—O semiconductors may be amorphous, polycrystalline, and microcrystalline ZnO doped with one or more impurity elements selected from the group 1 elements, group 13 elements, group 14 elements, group 15 elements, group 17 elements, etc., or not doped with any impurity element. In microcrystalline ZnO, amorphous ZnO and polycrystalline ZnO coexist.

According to the embodiments of the present invention, an organic EL display apparatus and active matrix substrate configured to allow a plurality of oxide semiconductor TFTs having different required characteristics to preferably coexist, can be provided.

This application is based on Japanese Patent Applications No. 2017-203350 filed on Oct. 20, 2017, the entire contents of which are hereby incorporated by reference.

What is claimed is:

1. An organic EL display apparatus having a plurality of pixels arranged in a matrix, comprising:
a substrate; and
a pixel circuit provided for each of the plurality of pixels,
wherein
the pixel circuit includes a plurality of oxide semiconductor TFTs supported on the substrate, the plurality of oxide semiconductor TFTs including a first oxide semiconductor TFT having a first oxide semiconductor layer and a second oxide semiconductor TFT having a second oxide semiconductor layer,
the first oxide semiconductor TFT has
the first oxide semiconductor layer disposed on a first insulating layer disposed on the substrate,
a first gate insulating layer disposed on the first oxide semiconductor layer,
a first gate electrode disposed on the first gate insulating layer, facing the first oxide semiconductor layer, and
a first source electrode and a first drain electrode electrically connected to the first oxide semiconductor layer, and
the second oxide semiconductor TFT has
a second gate electrode disposed on the substrate,
a second gate insulating layer covering the second gate electrode,
the second oxide semiconductor layer disposed on the second gate insulating layer, facing the second gate electrode,
a second source electrode and a second drain electrode electrically connected to the second oxide semiconductor layer, and
a shield electrode disposed on a second insulating layer disposed on the second oxide semiconductor layer, facing the second oxide semiconductor layer.

2. The organic EL display apparatus of claim 1, wherein
the pixel circuit includes a selection TFT, a drive TFT, and a capacitive element, and
the second oxide semiconductor TFT is the drive TFT.

3. The organic EL display apparatus of claim 2, wherein
the first oxide semiconductor TFT is the selection TFT.

4. The organic EL display apparatus of claim 1, wherein
a length of the second gate electrode in a channel length direction of the second oxide semiconductor TFT is greater than a length of the shield electrode in the channel length direction.

5. The organic EL display apparatus of claim 1, wherein
a fixed potential is applied to the shield electrode.

6. The organic EL display apparatus of claim 5, wherein
the fixed potential is a ground potential.

7. The organic EL display apparatus of claim 1, wherein
substantially the same potential that is applied to the second gate electrode is applied to the shield electrode.

8. The organic EL display apparatus of claim 1, wherein
the first insulating layer and the second gate insulating layer are disposed in the same layer,
the first oxide semiconductor layer and the second oxide semiconductor layer are disposed in the same layer,
the first gate insulating layer and the second insulating layer are disposed in the same layer,
the first gate electrode and the shield electrode are disposed in the same layer, and
the first source electrode, the first drain electrode, the second source electrode, and the second drain electrode are disposed in the same layer.

9. The organic EL display apparatus of claim 1, further comprising:
a protection layer covering the pixel circuit;
a pixel electrode disposed on the protection layer and electrically connected to the pixel circuit;
an organic EL layer disposed on the pixel electrode; and
an upper electrode disposed on the organic EL layer.

10. The organic EL display apparatus of claim 1, wherein
the first oxide semiconductor layer and the second oxide semiconductor layer each contain an In—Ga—Zn—O semiconductor.

11. The organic EL display apparatus of claim 10, wherein
the In—Ga—Zn—O semiconductor includes a crystalline portion.

12. An active matrix substrate having a display region defined by a plurality of pixel regions arranged in a matrix, and a peripheral region located around the display region, comprising:
a substrate; and
a peripheral circuit monolithically formed on the substrate in the peripheral region, wherein
the peripheral circuit includes a plurality of oxide semiconductor TFTs supported on the substrate, the plurality of oxide semiconductor TFTs including a first oxide semiconductor TFT having a first oxide semiconductor layer and a second oxide semiconductor TFT having a second oxide semiconductor layer,
the first oxide semiconductor TFT has
the first oxide semiconductor layer disposed on a first insulating layer disposed on the substrate,
a first gate insulating layer disposed on the first oxide semiconductor layer,
a first gate electrode disposed on the first gate insulating layer, facing the first oxide semiconductor layer, and
a first source electrode and a first drain electrode electrically connected to the first oxide semiconductor layer, and
the second oxide semiconductor TFT has
a second gate electrode disposed on the substrate,
a second gate insulating layer covering the second gate electrode,
the second oxide semiconductor layer disposed on the second gate insulating layer, facing the second gate electrode,
a second source electrode and a second drain electrode electrically connected to the second oxide semiconductor layer, and
a shield electrode disposed on a second insulating layer disposed on the second oxide semiconductor layer, facing the second oxide semiconductor layer.

13. The active matrix substrate of claim 12, wherein
a length of the second gate electrode in a channel length direction of the second oxide semiconductor TFT is greater than a length of the shield electrode in the channel length direction.

14. The active matrix substrate of claim 12, wherein
a fixed potential is applied to the shield electrode.

15. The active matrix substrate of claim 14, wherein
the fixed potential is a ground potential.

16. The active matrix substrate of claim 12, wherein
substantially the same potential that is applied to the second gate electrode is applied to the shield electrode.

17. The active matrix substrate of claim 12, wherein
the first insulating layer and the second gate insulating layer are disposed in the same layer,
the first oxide semiconductor layer and the second oxide semiconductor layer are disposed in the same layer,
the first gate insulating layer and the second insulating layer are disposed in the same layer,
the first gate electrode and the shield electrode are disposed in the same layer, and
the first source electrode, the first drain electrode, the second source electrode, and the second drain electrode are disposed in the same layer.

18. The active matrix substrate of claim 12, wherein
the first oxide semiconductor layer and the second oxide semiconductor layer each contain an In—Ga—Zn—O semiconductor.

19. The active matrix substrate of claim 18, wherein
the In—Ga—Zn—O semiconductor includes a crystalline portion.
